(19) United States
(12) Patent Application Publication
(10) Pub. No.: US 2019/0051359 A1
(43) Pub. Date: Feb. 14, 2019

(54) SEMICONDUCTOR MEMORY DEVICE AND METHOD FOR OPERATING THE SAME

(71) Applicant: SK hynix Inc., Icheon-si Gyeonggi-do (KR)

(72) Inventors: Deung Kak YOO, Icheon-si Gyeonggi-do (KR); Min Kyu PARK, Icheon-si Gyeonggi-do (KR); Soo Jin WI, Icheon-si Gyeonggi-do (KR)

(73) Assignee: SK hynix Inc., Icheon-si Gyeonggi-do (KR)

(21) Appl. No.: 15/920,757

(22) Filed: Mar. 14, 2018

(30) Foreign Application Priority Data
Aug. 14, 2017 (KR) 10-2017-0103151

(51) Int. Cl. G11C 16/26; G11C 16/10

(52) U.S. Cl. CPC G11C 16/26; G11C 16/10

(57) ABSTRACT

A semiconductor memory device includes a status storage unit and a status check unit. The status storage unit stores first status data indicating an operation status of the memory cell array. The status check unit generates second status data, based on the first status data and an operation of the memory cell array.

### CROSS-REFERENCE TO RELATED APPLICATION

The present application claims priority under 35 U.S.C. § 119(a) to Korean patent application number 10-2017-0103151 filed on Aug. 14, 2017 in the Korean Intellectual Property Office, the entire disclosure of which is incorporated herein by reference.

### BACKGROUND

### 1. Technical Field

An aspect of the present disclosure relates to an electronic device, and more particularly, to a semiconductor memory device and a method for operating the same.

### 2. Related Art

Memory devices may be formed in a two-dimensional structure in which strings are arranged horizontally to a semiconductor substrate, or may be formed in a three-dimensional structure in which strings are vertically arranged in relation to a semiconductor substrate. A three-dimensional semiconductor device is a memory device devised to overcome the limit of degree of integration in two-dimensional semiconductor devices, and may include a plurality of memory cells vertically stacked on a semiconductor substrate.

### SUMMARY

Embodiments provide a semiconductor memory device capable of improving the reliability of an operation of the semiconductor memory device.

Embodiments also provide a method for operating a semiconductor memory device capable of improving the reliability of an operation of the semiconductor memory device.

According to an aspect of the present disclosure, there is provided a semiconductor memory device including: a status storage unit configured to store first status data indicating an operation status of a memory cell array; and a status check unit configured to generate second status data, based on the first status data and an operation of the memory cell array.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey a scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a block diagram illustrating a semiconductor system including a semiconductor memory device and a controller in accordance with at least one aspect of the present disclosure.

FIG. 2 is a block diagram illustrating a semiconductor system including a semiconductor memory device and a controller according to the present disclosure.

FIG. 3 is a block diagram illustrating a semiconductor memory device according to an embodiment of the present disclosure.

FIG. 4 is a block diagram illustrating an exemplary embodiment of a status check unit shown in FIG. 2.

FIG. 5A is a block diagram illustrating an embodiment of an operation check unit of FIG. 4.

FIG. 5B is a block diagram illustrating another embodiment of the operation check unit of FIG. 4.

FIG. 5C is a block diagram illustrating still another embodiment of the operation check unit of FIG. 4.

FIG. 6 is a block diagram illustrating an embodiment of a read/write circuit of FIG. 3.

FIG. 7 is a circuit diagram illustrating an exemplary embodiment of a current sensing circuit of FIG. 5B.

FIG. 8 is a block diagram illustrating another embodiment of the status check unit shown in FIG. 2.

FIG. 9 is a block diagram illustrating still another embodiment of the status check unit shown in FIG. 2.

FIG. 10 is a block diagram illustrating still another embodiment of the status check unit shown in FIG. 2.

FIG. 11 is a flowchart illustrating a method for operating the semiconductor memory device according to an embodiment of the present disclosure.

FIG. 12 is a block diagram illustrating a memory system including the semiconductor memory device of FIG. 3.

FIG. 13 is a block diagram illustrating an application example of the memory system of FIG. 12.

FIG. 14 is a block diagram illustrating a computing system including the memory system described with reference to FIG. 13.

### DETAILED DESCRIPTION

In the following detailed description, only certain exemplary embodiments of the present disclosure have been shown and described, simply by way of illustration. As those skilled in the art would realize, the described embodiments may be modified in various different ways, all without departing from the spirit or scope of the present disclosure. Accordingly, the drawings and description are to be regarded as illustrative in nature and not restrictive.

In the entire specification, when an element is referred to as being “connected” or “coupled” to another element, it can be directly connected or coupled to the another element or be indirectly connected or coupled to the other element with one or more intervening elements interposed therebetween. In addition, when an element is referred to as “including” a component, this indicates that the element may further include another component instead of excluding another component unless there is different disclosure.

Hereinafter, exemplary embodiments of the present disclosure will be described in detail with reference to the accompanying drawings. The same reference numerals are used to designate the same elements as those shown in other drawings. In the following descriptions, only portions necessary for understanding operations according to the exemplary embodiments may be described, and descriptions of the other portions may be omitted so as to not obscure important concepts of the embodiments.

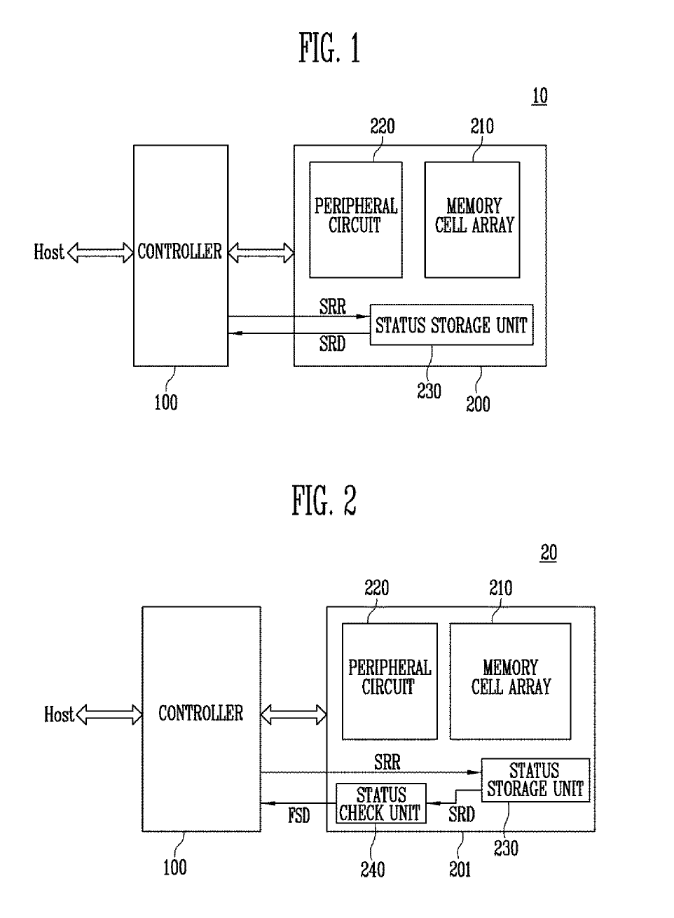

FIG. 1 is a block diagram illustrating a semiconductor system including a semiconductor memory device and a controller in accordance with at least one aspect of the present disclosure.

Referring to FIG. 1, the semiconductor system 10 includes a semiconductor memory device 200 and a controller 100. Also, the semiconductor system 10 is coupled to a host HOST that is a user device.

The semiconductor memory device 200 is a device that operates in response to control of the controller 100. The semiconductor memory device 200 may be provided as an integrated circuit on at least one chip, and may be configured to operate a specific operation in response to control of the controller 100. For example, the semiconductor memory device 200 may be provided as a nonvolatile memory device or a volatile memory device. The semiconductor memory device 200 may be configured as a solid state disk, a solid state driver (SSD), a personal computer memory card international association (PCMCIA) card, a compact flash card (CFC), a smart media card (SMC), a memory stick, a multimedia card (MMC, RS-MMC, MMC-micro), an SD card (SD, Mini-SD, Micro-SD, SDHC), a universal flash storage (UFS), or the like.

The semiconductor memory device 200 includes a memory cell array 210 and a peripheral circuit 220. The semiconductor memory device 200 further includes a status storage unit 230.

The memory cell array 210 includes a plurality of memory cells. The peripheral circuit 220 is configured to perform a program operation, a read operation, an erase operation, and the like on the memory cell array 210 in response to a command from the controller 100. In a program operation, the peripheral circuit 220 may receive data from the controller 100, and store the received data in selected memory cells of the memory cell array 210. In a read operation, the peripheral circuit 220 may read data stored in selected memory cells of the memory cell array 210, and output the read data to the controller 100. In an erase operation, the peripheral circuit 220 may erase data stored in selected memory cells of the memory cell array 210. Although not shown in FIG. 1, the semiconductor memory device 200 further includes a control logic that controls the peripheral circuit 220 to perform the program operation, the read operation, and the erase operation on the memory cell array 210. The status storage unit 230 receives a status read request (SRR) from the controller 100, and transfers status read data (SRD) to the controller 100.

The controller 100 is coupled between the host HOST and the semiconductor memory device 200. The controller 100 may transmit a command to the semiconductor memory device 200 in response to a request from the host HOST. The semiconductor memory device 200 may execute the received command. The host HOST may be configured as a device such as a personal or portable computer, a personal digital assistant (PDA), a portable media player (PMP), or an MP3 player. The host HOST and the semiconductor system 10 may be coupled to each other by a standardized interface such as USB, SCSI, ESDI, SATA, SAS, PCI-express, or IDE interface.

In an embodiment, the controller 100 may control the semiconductor memory device 200 to perform a program operation, a read operation, an erase operation, or the like in response to a request from the host HOST. In a program operation, the controller 100 may provide a command (hereinafter, referred to as a program command) corresponding to the program operation, an address, and data to the semiconductor memory device 200. The semiconductor memory device 200 may program data in memory cells indicated by the address. In a read operation, the controller 100 may provide a command (hereinafter, referred to as a read command) corresponding to the read operation and an address to the semiconductor memory device 200. The semiconductor memory device 200 may read data from memory cells indicated by the address, and output the read data to the controller 100. In an erase operation, the controller 100 may provide a command (hereinafter, referred to as an erase command) and an address to the semiconductor memory device 200. The semiconductor memory device 200 may erase data stored in memory cells indicated by the address.

The controller 100 transmits a command to the semiconductor memory device 200 and then checks whether performance of an operation according to the corresponding command has completed. Also, the controller 100 may check whether the performance of the operation according to the corresponding command has succeeded or failed. For this check, the controller 100 may transmit a program command, a read command, or an erase command and then perform a status read on the semiconductor memory device 200. If the controller 100 transmits a status read request SRR to the semiconductor memory device 100, the semiconductor memory device 200 may provide status read data SRD to the controller 100. In this case, the semiconductor memory device 200 may transfer, to the controller 100, information on whether the operation according to the command has completed, whether the operation according to the command is being performed, or whether the operation according to the command has failed, through the status read data SRD. More specifically, the status read request SRR received from the controller 100 is transferred to the status storage unit 230 of the semiconductor memory device 200. In response to the status read request SRR, the semiconductor memory device 200 transfers the status read data SRD stored in the status storage unit 230 to the controller 100.

In the general semiconductor system 10 shown in FIG. 1, the controller 100 determines whether the operation corresponding to the command transferred to the semiconductor memory device 200 has succeeded or failed, by checking the received status read data SRD. The status read data SRD is generally stored as a value indicating “operation success” which may be a default value. When performance of an operation has not completed or when a malfunction or the like occurs during the operation, the status read data SRD is updated with a value indicating “operation failure.” In some situations, e.g., when a power voltage is not supplied smoothly, the status read data SRD might not be updated with a value indicating “operation failure” even if performance of the operation according to the received command has not completed normally. In this case, although the performance of the operation according to the command has failed, the status read data SRD transferred to the controller 100 may have a value indicating “operation success.” Therefore, the operational reliability of the semiconductor memory device may deteriorate in the above-described situation. Accordingly, a structure is required, which can further improve the operational reliability of the semiconductor memory device with respect to a determination that an abnormal operation has passed.

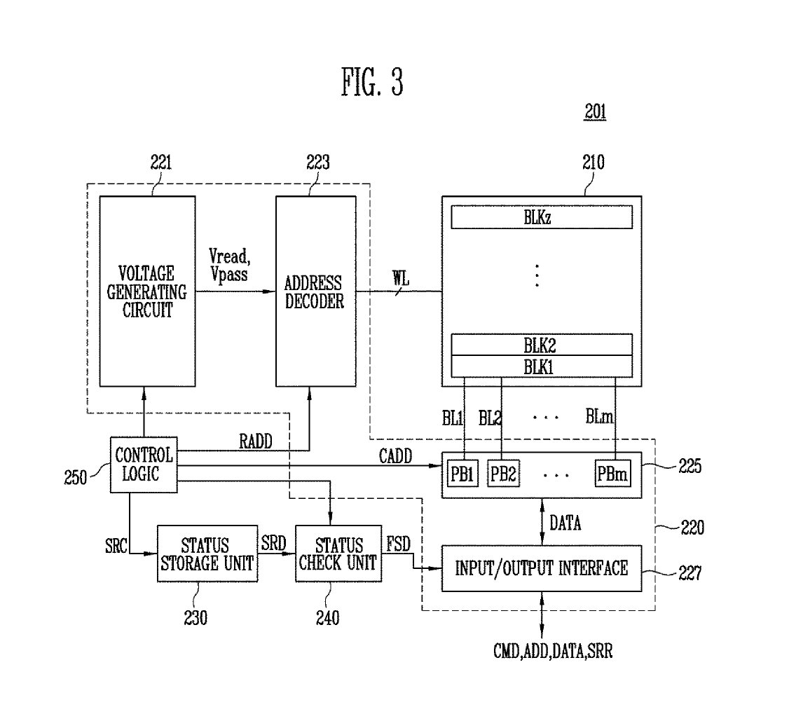

FIG. 2 is a block diagram illustrating a semiconductor system including a semiconductor memory device and a controller according to the present disclosure.

Referring to FIG. 2, the semiconductor system 20 includes a semiconductor memory device 201 and a controller 100 according to the present disclosure. Also, the semiconductor system 20 is coupled to a host HOST that is a user device.

In the semiconductor system 20, the controller 100 transmits a command to the semiconductor memory device 201 and then checks whether performance of an operation has completed according to the corresponding command. Also, the controller 100 may check whether the performance of the operation has succeeded or failed according to the corresponding command. For this check, the controller 100 may transmit a program command, a read command, or an erase command and then perform status read on the semiconductor memory device 201. If the controller 100 transmits a status read request SRR to the semiconductor memory device 201, the semiconductor memory device 201 may provide final status data FSD to the controller 100. In this case, the semiconductor memory device 201 may transfer, to the controller 100, information on whether the operation according to the command has completed, whether the operation according to the command is being performed, or whether the operation according to the command has failed, through the final status data FSD. More specifically, the status read request SRR received from the controller 100 is transferred to a status storage unit 230 of the semiconductor memory device 201. The status storage unit 230 outputs status read data SRD, corresponding to the status read request SRR. A status check unit 240 of the semiconductor memory device 201 according to the present disclosure receives status read data SRD and outputs final status data FSD, based on the received status read data SRD. The final status data FSD is transferred from the semiconductor memory device 201 to the controller 100.

That is, the semiconductor memory device 201 according to the present disclosure includes the status check unit 240 that receives status read data SRD from the status storage unit 230 and outputs final status data FSD. The final status data FSD is generated based on the status read data SRD. In addition to the status read data SRD, the final status data FSD complementarily includes information on an additional operation check with respect to an operation status of the semiconductor memory device 201. Thus, although the status read data SRD might not be updated to a value indicating “operation failure” even if the performance of the operation has not completed normally, the semiconductor memory device 201 generates final state data FSD through the additional operation check and transmits the generated final state data FSD to the controller 100. Accordingly, the operational reliability of the semiconductor memory device 201 and the memory system 20 is improved.

FIG. 3 is a block diagram illustrating a semiconductor memory device according to an embodiment of the present disclosure.

Referring to FIG. 3, the semiconductor memory device 201 according may include a memory cell array 210 configured to store data, a peripheral circuit 220 configured to perform an erase operation, a program operation, a read operation, and the like on the memory cell array 210, and a control logic 250 configured to control the peripheral circuit 220. Also, the semiconductor memory device 201 further includes a status storage unit 250 and a status check unit 240. The status storage unit 250 stores an operation status of the memory cell array 210 as status read data SRD. The status check unit 240 generates final status data FSD, based on the status read data SRD and the operation of the memory cell array 210. The generated final status data FSD may be transferred to the controller 100 through an input/output interface 227.

The memory cell array 210 includes a plurality of memory blocks (not shown), and the memory blocks include a plurality of cell strings (not shown). For example, the cell strings include drain select transistors, memory cells, and source select transistors, and are coupled to bit lines BL. Gates of the drain select transistors are coupled to drain select lines DSL, gates of the memory cells are coupled to word lines WL, and gates of the source select transistors are coupled to source select lines SSL.

The peripheral circuit 220 includes a voltage generating circuit 221, an address decoder 223, a read/write circuit 225, and the input/output interface 227. The voltage generating circuit 221 generates operating voltages necessary for various operations under control of the control logic 250. For example, the voltage generating circuit 221 may generate a read voltage Vread and a pass voltage Vpass, which are necessary for a data read operation. Also, the voltage generating circuit 221 generates, as the operating voltages, a program voltage including a plurality of program pulses, a program pass voltage, a verify voltage, an erase voltage, and the like.

The address decoder 223 transfers operating voltages to drain select lines DSL, word lines WL, and source select lines SSL, which are coupled to a selected memory block among the plurality of memory blocks included in the memory cell array 210, in response to a row address RADD.

The read/write circuit 225 exchanges data with the memory cell array 210 in response to a column address CADD. Also, the read/write circuit 225 includes a plurality of page buffer units PB1 to PBm respectively coupled to bit lines BL1 to BLm of the memory cell array 210.

The input/output interface 227 receives a command CMD, data DATA, and an address ADD from the outside. Also, the input/output interface 227 receives a status read request SRR. In a status check operation, the input/output interface 227 receives final status data from the status check unit 240 and outputs the received final status data to the outside.

The control logic 250 may control overall operations of the semiconductor memory device 201 in response to the received command CMD and address ADD. If a status read request SRR is received from the outside, the control logic 250 outputs a status read control signal SRC to the status storage unit 230. The status storage unit 230 may store an operation status of the memory cell array 210 as status read data SRD. The status storage unit 230 outputs status read data SRD to the status check unit 240, based on the status read control signal SRC received from the control logic 250. The status checking check unit 240 checks an operation of the memory cell array 210, and generates the checked result as status check data. Also, the status check unit 240 generates final status data FSD, based on the status read data SRD and the status check data, and outputs the generated final status data FSD to the input/output interface 227. In this specification, the status read data SRD may also be referred to as first status data. Also, in this specification, the final status data may also be referred as second status data.

The first status data, i.e., the status read data SRD may be a status value indicating whether a specific operation, e.g., a program operation of the memory cell array 210 has succeeded or failed. The status storage unit 230 may be implemented with a status register. In a general case, whether an operation according to a command has succeeded or failed is determined by the checking status read data SRD. The status read data SRD is generally stored as a value indicating “operation success” which may be a default value. When an operation has not completed during performance of the operation or when a malfunction or the like occurs during the operation, the status read data SRD is updated with a value indicating “operation failure.” In some situations, e.g., when a power voltage is not supplied smoothly, the status read data SRD might not be updated with a value indicating “operation failure” even if performance of the operation according to the received command has not completed normally. In this case, although performance of the operation according to the command has failed, the status read data SRD may be transferred as a value indicating an “operation success” to the controller 100 as shown in FIG. 1. Therefore, the operational reliability of the semiconductor memory device may deteriorate in the above-described situation.

The semiconductor memory device 201 according to an embodiment of the present disclosure may generate status check data indicating whether an operation according to a command has been normally performed, through the status check unit 240. Also, the semiconductor memory device 201 according to an embodiment of the present disclosure may generate final status data FSD, based on status read data SRD, and the status check data. Instead of the status read data SRD, the generated final status data FSD is transferred to the controller 100. Accordingly, although performance of an operation according to a command is not performed normally, the status read data SRD stored in the status storage unit 230 may have a value indicating “operation success.” However, in this case, a more reliable operation check is possible through an additional status check performed by the status check unit 240. Accordingly, it is possible to prevent a situation in which an abnormal program pass is transferred as the status read data to the controller. A more detailed configuration and operation of the status check unit 240 will be described later with reference to FIGS. 4 to 11.

FIG. 4 is a block diagram illustrating an exemplary embodiment of the status check unit shown in FIG. 2.

Referring to FIG. 4, the status check unit 300 may include an operation check unit 310 and a logical sum circuit (OR circuit) 330. As shown in FIG. 4, the OR circuit 330 may be configured as a logical sum gate (OR gate). The operation check unit 310 may generate status check data SC by checking an operation of the memory cell array 210. The OR circuit 330 may receive and perform a logical sum operation on status read data SRD input from the status storage unit 230 and status check data SC input from the operation check unit 310, and output the result of the logical sum operation as final state data FSD.

As described above, the status read data SRD stored in the status storage unit 230 is generally stored as a value indicating “operation success” which may be a default value. When an operation is being performed or when a malfunction or the like occurs during the operation, the status read data SRD is updated with a value indicating that “the operation has not completed normally.” In an exemplary embodiment, the value indicating “operation success” may be a logical value of “0,” and the value indicating “operation incomplete” may be a logical value of “1.” When the status read data SRD is updated with the logical value of “1,” the OR circuit 330 outputs the logical value of “1,” regardless of the logical value indicated by the status check data SC. The logical value of “1” is transferred to the controller 100 through the input/output interface 227, and thus the controller 100 can recognize that the operation of the semiconductor memory device 201 has not completed normally.

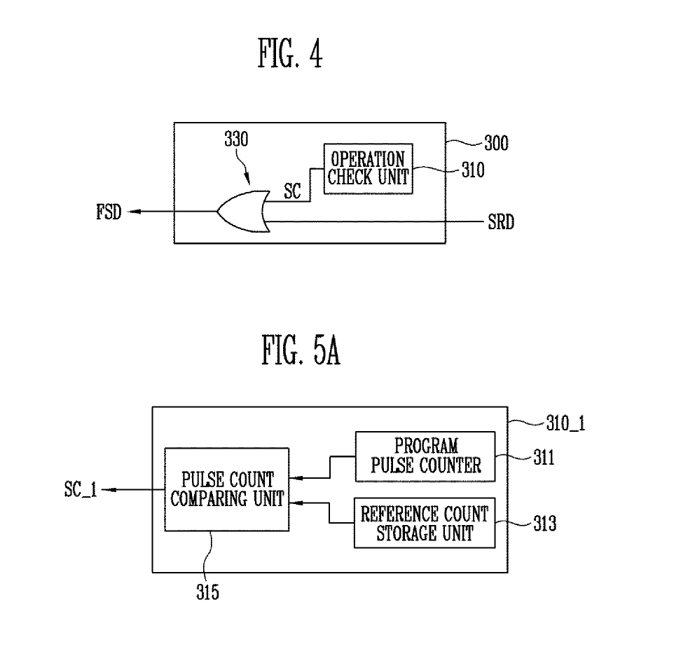

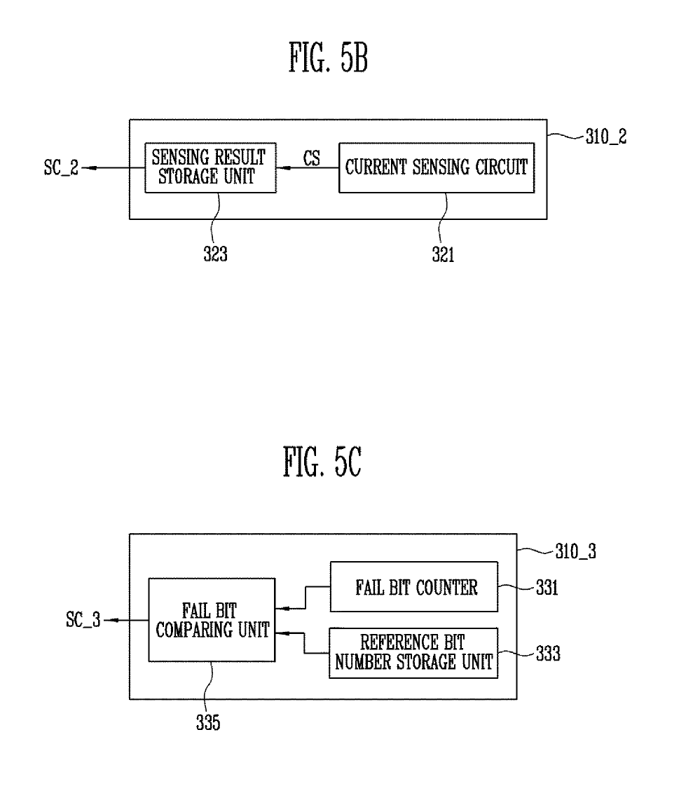

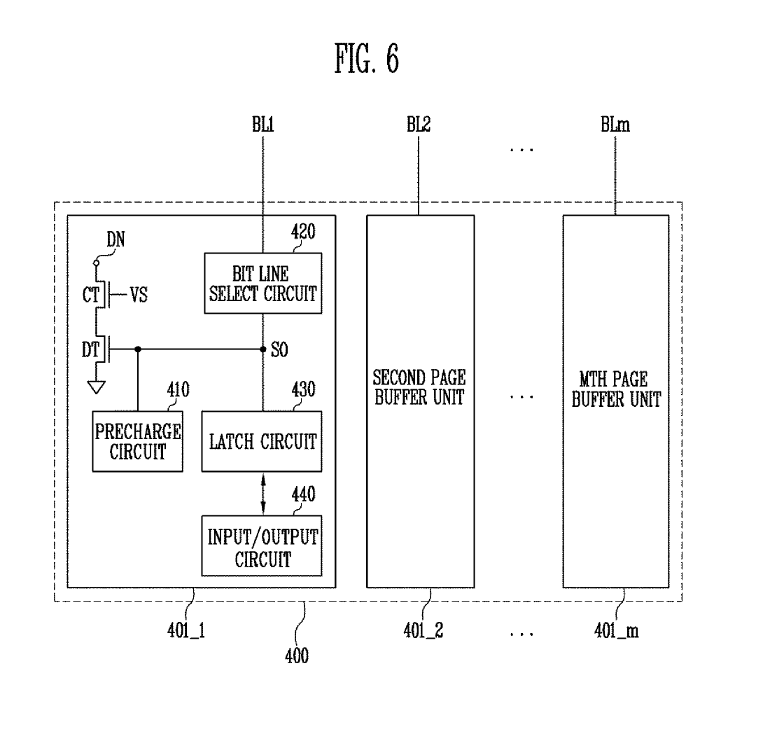

In the above-described example, when the status read data SRD maintains the logical value of “0” even though performance of the operation has not completed normally, the OR circuit 330 outputs final status data FSD which depends on the value of the status check data SC. That is, when the status check data SC indicates the logical value of “0,” the final status data FSD indicates the logical value of “0.” When the status check data SC indicates the logical value of “1,” the final status data FSD indicates the logical value of “1.” The operation check unit 310 outputs the logical value of “1” as the status check data SC when the operation of the memory cell array 210 has not completed, and outputs the logical value of “0” as the status check data SC when the operation of the memory cell array 210 is completed. The process in which the operation check unit 310 checks whether operation of the memory cell array 210 has completed differs from the process in which status read data SRD stored in the status storage unit 230 is updated. Thus, although the status read data SRD is not updated in an abnormal situation, the operation check unit 310 can normally check whether the operation of the memory cell array 210 has completed. An exemplary configuration of the operation check unit 310 will be described with reference to FIGS. 5A to 7.

In FIG. 4, the OR circuit 330 that performs a logical sum operation on the status check data SC and the status read data SRD is included in the status check unit 300. However, a logical multiplication circuit (AND circuit) may be used rather than the OR circuit 330. That is, in FIG. 4, a relationship among the status check data SC, the read data SRD, and the final status data FSD is as shown in Equation 1.

FSD=SC+SRD Equation 1

Referring to the following Equation 2, it can be seen that the final status data FSD may be deduced through a logical multiplication operation.

(̅S̅C̅·̅S̅R̅D̅)̅=SC+SRD Equation 2

Therefore, the final status data FSD may be generated by performing a logical negation operation (NOT operation) on the status check data SC and the status read data SRD and then performing a logical multiplication operation (AND operation) through an AND circuit, and again performing the NOT operation on the result of the performed operations. In an embodiment, the AND circuit may be configured as a logical multiplication gate (AND gate).

FIG. 5A is a block diagram illustrating an embodiment of the operation check unit of FIG. 4.

Referring to FIG. 5A, the operation check unit 310_1 includes a program pulse counter 311, a reference count storage unit 313, and a pulse count comparing unit 315. The program pulse counter 311 counts a number of times that a program pulse is applied to the memory cell array 110 in a program operation of the memory cell array 110. The reference count storage unit 313 stores a reference count value that is a reference compared with a count of the number of times that the program pulse is applied. The reference count storage unit 313 may store the reference count value which may become a generation reference of the status check data SC_1. The pulse count comparing unit 315 generates status check data SC_1 by comparing the reference count value with the number of times that the program pulse is applied.

The program pulse counter 311 initially stores a value of 0. The program pulse counter 311 performs an update by increasing the stored value by 1 whenever the program pulse is applied to the memory cell array 110.

For example, the reference count value stored in the reference count storage unit 313 may be generally determined as a number of times that the program pulse is generally applied until the program operation is completed or a value less than the number of times that the program pulse is applied. For example, when the program pulse is generally applied ten times until the program operation is completed, the program operation has not completed when the program pulse is applied only twice or so. If the status read data SRD stored in the status storage unit 230 is not updated normally, the logical value of “0,” which indicates program completion, may be stored in the status storage unit 230.

In the above-described situation, if the reference count value stored in the reference count storage unit 313 is 3, the pulse count comparing unit 315 outputs the logical value of “1” when the number of times that the program pulse is applied is less than 3, and outputs the logical value of “0” when the number of times that the program pulse is applied is greater than or equal to 3. Thus, in this case, the status check unit 300 outputs final status data FSD indicating the logical value of “1” regardless of the value of the status read data RSD when the number of times that the program pulse is applied is 1 or 2. When the program pulse is applied 3 or more times, the status check unit 300 outputs final status data FSD according to the value of the status read data SRD. The reference count value may be experimentally determined, if necessary.

As described above, the status check unit 240 of the semiconductor memory device 201 according to the embodiment of the present disclosure subsidiarily determines whether the program operation has completed according to the number of times that program pulse is applied, so that it is possible to prepare for a case where the status read data SRD stored in the status storage unit 230 has not been updated normally. In particular, it is possible to correct an error occurring when the status storage unit 230 has not been updated normally in an early stage of the program operation.

FIG. 5B is a block diagram illustrating another embodiment of the operation check unit of FIG. 4.

Referring to FIG. 5B, the operation check unit 310_2 includes a current sensing circuit (CSC) 321 and a sensing result storage unit 323. The CSC 321 generates a check signal CS indicating whether, in a program operation of the memory cell array 210, at least some memory cells among selected memory cells have reached a target threshold voltage. The sensing result storage unit 323 stores the check signal CS as status check data SC_2.

The CSC 321 generates a check signal CS corresponding to the logical value of “1” when the number of memory cells that reach the target threshold voltage among the selected memory cells to be programmed is less than a predetermined first reference value, based on a bit set signal which will be described later. The CSC 321 generates a check signal CS corresponding to the logical value of “0” when the number of memory cells that reach the target threshold voltage among the selected memory cells to be programmed is great than or equal to the predetermined first reference value, based on the bit set signal. Thus, the sensing result storage unit 323 stores status check data SC_2 corresponding to the logical value of “1” or the logical value of “0”, based on the check signal CS.

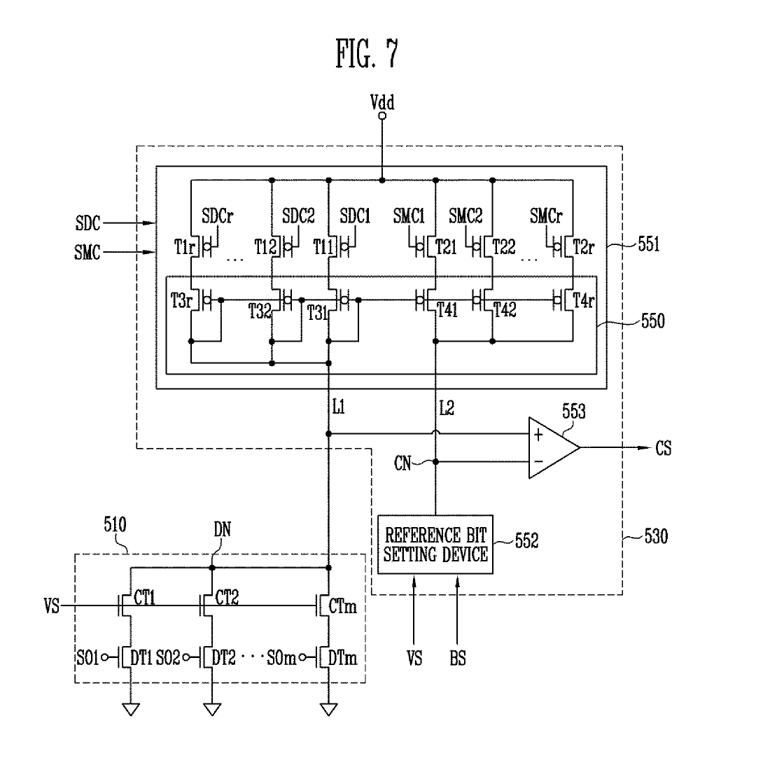

The CSC 321 may be configured in various ways, if necessary. An exemplary embodiment of the CSC 321 will be described later with reference to FIGS. 6 and 7.

FIG. 5C is a block diagram illustrating still another embodiment of the operation check unit of FIG. 4.

Referring to FIG. 5C, the operation check unit 310_3 includes a fail bit counter 331, a reference bit number storage unit 333, and a fail bit comparing unit 335. In a program operation, the fail bit counter 331 counts a number of memory cells that do not reach a threshold voltage among selected memory cells to be programmed. The reference bit number storage unit 333 stores a reference bit number that becomes a generation reference of status check data SC_3. The fail bit comparing unit 335 generates the status check data SC_3 by comparing the reference bit number stored in the reference bit number storage unit 333 with the counted result of the fail bit counter 331.

The fail bit counter 331 may count a number of memory cells on which programming fails during the program operation. In an embodiment, the fail bit counter 331 may apply a verify voltage to count a number of memory cells that have threshold voltages lower than the verify voltage. The fail bit counter 331 may be variously configured, if necessary.

The fail bit comparing unit 335 compares the number of memory cells on which a program operation failed, which is counted by the fail bit counter 331, with the reference bit number. The fail bit comparing unit 335 generates the logical value of “1” as the status check data SC_3 when the counted result is greater than the reference bit number, and generates the logical value of “0” as the status check data SC_3 when the counted result is less than or equal to the reference bit number. Thus, when the number of memory cells that do not reach the target threshold voltage is greater than the reference bit number, the operation check unit 310_3 outputs the logical value of “1.” In this case, the status check unit 240 outputs the logical value of “1” regardless of the status read data SRD. When the number of memory cells that do not reach the target threshold voltage is less than or equal to the reference bit number, the operation check unit 310_3 outputs the logical value of “1” as final status data FSD. In this case, the status check unit 240 outputs final status data FSD which depends on the status read data SRD.

FIG. 6 is a block diagram illustrating an embodiment of the read/write circuit of FIG. 3.

Referring to FIG. 6, the read/write circuit 400 includes first to mth page buffer units 401_1 to 401_m. The first to mth page buffer units 401_1 to 401_m of FIG. 6 may correspond to the page buffer units PB1 to PBm shown in FIG. 3, respectively. In FIG. 6, internal components of the second to mth page buffer units 401_2 to 401_m are omitted for convenience of description. However, it will be understood that the second to mth page buffer units 401_2 to 401_m are configured in a substantially similar manner to the first page buffer unit 401_1.

The first page buffer unit 401_1 includes a precharge circuit 410, a bit line select circuit 420, a latch circuit 430, an input/output circuit 440, and a control transistor CT and a detection transistor DT, which are coupled in series between a detection node DN and ground.

The precharge circuit 410 is coupled to a sensing node S0. If a verify operation is started, the precharge circuit 410 is configured to precharge the sensing node S0 to a predetermined voltage.

The bit line select circuit 420 is coupled between a first bit line BL1 and the sensing node S0. The bit line select circuit 420 is configured to allow the sensing node S0 and the first bit line BL1 to be electrically coupled to each other after the sensing node S0 is precharged. The voltage of the sensing node S0 is determined according to the threshold voltage of a corresponding memory cell.

The latch circuit 430 stores a data bit corresponding to the voltage of the sensing node S0. That is, the latch circuit 430 stores data corresponding to the threshold voltage of the corresponding memory cell. The latch circuit 430 may include at least one latch. The data stored in the latch circuit 430 is again reflected to the sensing node S0.

The input/output circuit 440 is coupled between the latch circuit 430 and the input/output interface 227 (see FIG. 3). The input/output circuit 440 outputs data temporarily stored in the latch circuit 430 to the input/output interface 227 in a read operation, and transfers data provided from the input/output interface 227 to the latch circuit 430 in a program operation.

The control transistor CT is turned on or turned off in response to a verify signal VS. The verify signal VS is received from the control logic 250. The detection transistor DT is turned on or turned off according to the voltage of the sensing node S0. Consequently, the voltage of the detection node DN may be determined according to the voltage of the sensing node S0.

Although not shown in FIG. 6, detection nodes DN of the page buffer units are commonly coupled. In addition, the detection node DN is coupled to a pass/fail check circuit 530.

FIG. 7 is a circuit diagram illustrating an exemplary embodiment of the current sensing circuit of FIG. 5B.

Referring to FIG. 7, the current sensing circuit includes a detector 510 and a pass/fail check circuit 530. The detector 510 includes a plurality of control transistors CT1 to CTm and a plurality of detection transistors DT1 to DTm. As described with reference to FIG. 6, each control transistor (e.g., CT1) and each detection transistor (e.g., DT1) are included in one page buffer unit (e.g., PB1 of FIG. 3). That is, the plurality of control transistors CT1 to CTm and the plurality of detection transistors DT1 to DTm are included in the read/write circuit 225.

One control transistor (e.g., CT1) and one detection transistor (e.g., DT1) are coupled in series between a detection node DN and a reference node. The plurality of control transistors CT1 to CTm and the plurality of detection transistors DT1 to DTm are coupled in parallel between the detection node DN and the reference node. The plurality of control transistors CT1 to CTm and the plurality of detection transistors DT1 to DTm provide paths through which a current flowing through a first line L1 is discharged to the reference node.

The plurality of control transistors CT1 to CTm receive a verify signal VS from the control logic 250. The plurality of control transistors CT1 to CTm may turn on in response to the verify signal VS. In a verify operation, the verify signal VS may be activated as the logical value of “1,” and the plurality of control transistors CT1 to CTm may turn on.

First to mth detection transistors DT1 to DTm operate in response to first to mth sensing nodes S01 to S0m. In an exemplary embodiment, each sensing node may have the logical value of “1” when the threshold voltage of a corresponding memory cell is less than a verify voltage. At this time, the corresponding memory cell corresponds to a memory cell of a program failure. Each sensing node may have the logical value of “0” when the threshold voltage of a corresponding memory cell is greater than the verify voltage. At this time, the corresponding memory cell corresponds to a memory cell associated with a program operation passes.

As the program operation and the verify operation are repeated, the number of sensing nodes S01 to S0m having the logical value of “0” may increase, and the number of sensing nodes S01 to S0m having the logical value of “1” may decrease. That is, the number of detection transistors that turn on may decrease. Therefore, the paths through which the current flowing through the first line L1 is discharged to the reference node may be blocked. Consequently, the voltage of the detection node DN may increase.

The pass/fail check circuit 530 includes a current mirror 551, a reference bit setting device 552, and a comparator 553.

The current mirror 551 is coupled to the detector 510 through the first line L1, and is coupled to the reference bit setting device 552 through a second line L2. The current mirror 551 receives a power voltage through a power node Vdd. The current mirror 551 receives sensing current control signals SDC and mirroring current control signals SMC from the control logic 250, and operates according to the sensing current control signals SDC and the mirroring current control signals SMC.

The sensing current control signals SDC shown in FIG. 7 refer to first to rth sensing current control signals SDC1 to SDCr, and the mirroring current control signals SMC shown in FIG. 7 refer to first to rth mirroring current control signals SMC1 to SMCr.

The current mirror 551 includes a current mirror unit 550, a plurality of first transistors T11 to T1r, and a plurality of second transistors T21 to T2r.

The current mirror 551 mirrors the current flowing through the first line L1 to the second line L2. The current mirror 551 includes a plurality of third transistors T31 to T3r coupled to the first line L1 and a plurality of fourth transistors T41 to T4r coupled to the second line L2. In FIG. 7, it is illustrated that the plurality of third transistors T31 to T3r and the plurality of fourth transistors T41 to T4r are provided. However, this is illustrative, and one or more third transistors coupled to the first line L1 and one or more fourth transistors coupled to the second line L2 may be provided.

The plurality of third transistors T31 to T3r are coupled between the first line L1 and the plurality of first transistors T11 to T1r, respectively. Each of the plurality of third transistors T31 to T3r has a gate and a drain, which are coupled to each other. The plurality of fourth transistors T41 to T4r are coupled between the second line L2 and the plurality of second transistors T21 to T2r, respectively. Gates of the plurality of third transistors T31 to T3r and the plurality of fourth transistors T41 to T4r are coupled to each other.

The plurality of transistors T11 to T1r are coupled in parallel between the power node Vdd and the current mirror unit 550. The plurality of transistors T11 to T1r turn on or turn off in response to the first to rth sensing current control signals SDC1 to SDCr, respectively. The plurality of second transistors T21 to T2r are coupled in parallel between the power node Vdd and the current mirror unit 550. The plurality of second transistors T21 to T2r may turn on in response to the first to rth mirroring current control signals SMC1 to SMCr, respectively.

The sensing current control signals SDC1 to SDCr and the mirroring current control signals SMC1 to SMCr are controlled, so that currents flowing through the first and second lines L1 and L2 can be controlled. In an exemplary embodiment, the number of transistors that may turn on among the plurality of first transistors T11 to T1r may be controlled according to the sensing current control signals SDC1 to SDCr, and the amount of current flowing through the first line L1 may be controlled. For example, as the number of transistors that may turn on among the plurality of first transistors T11 to T1r decreases, the amount of current flowing through the first line L1 may decrease.

In an exemplary embodiment, the number of transistors that may turn on among the plurality of second transistors T21 to T2r may be controlled according to the mirroring current control signals SMC1 to SMCr, and the amount of current flowing through the second line L2 may be controlled. For example, as the number of transistors that turn on among the plurality of second transistors T21 to T2r decreases, the amount of current flowing through the second line L2 may decrease.

The reference bit setting device 552 is coupled to the current mirror 551 through the second line L2. The reference bit setting device 552 operates in response to the verify signal VS. The reference bit setting device 552 receives bit set signals BS from the control logic 250 (see FIG. 3). The impedance value of the reference bit setting device 552 is controlled according to the bit set signals BS. The bit set signals BS may correspond to the minimum number of memory cells associated with a program operation fails so as to consider the result of the verify operation as pass. That is, the bit set signals BS may correspond to the first reference value described with reference to FIG. 5B. When the impedance value of the reference bit setting device 552 increases, the voltage of a comparison node CN may increase.

The comparator 553 is configured to compare voltages of the detection node DN and the comparison node CN and generate a check signal CS. When the voltage of the detection node DN is greater than that of the comparison node CN, the check signal CS may be activated. The control logic 250 receiving the activated check signal CS may terminate the program. When the voltage of the detection node DN is less than that of the comparison node CN, the check signal CN may be non-activated. The control logic 250 may control the semiconductor memory device 201 to re-perform the program operation in response to the non-activated check signal CS.

It is assumed that the same current flows through the first and second lines L1 and L2. The voltage of the comparison node CN is determined according to the impedance value of the reference bit setting device. In addition, as the program operation and the verify operation are repeatedly performed, the number of transistors that may turn on among the first to mth detection transistors DT1 to DTm decreases, and the voltage of the detection node DN increases. When the number of transistors that may turn on among the first to mth detection transistors DT1 to DTm reaches the minimum number corresponding to the bit set signals BS, the voltage of the detection node DN becomes greater than that of the comparison node CN. Accordingly, the check signal CS is activated.

As described above, when the number of memory cells that reach the target threshold voltage among the selected memory cells is less than the predetermined first reference value, the check signal CS is not activated, and thus the status check data SC_2 having the logical value of “1” is stored in the sensing result storage unit 323. In addition, when the number of memory cells that reach the target threshold voltage among the selected memory cells is greater than or equal to the predetermined first reference value, the check signal CS is activated, and thus the status check data SC_2 having the logical value of “0” is stored in the sensing result storage unit 323.

The current sensing circuit described with reference to FIGS. 6 and 7 is illustrative, and various types of current sensing circuits may be used as the current sensing circuit 321 of FIG. 5B.

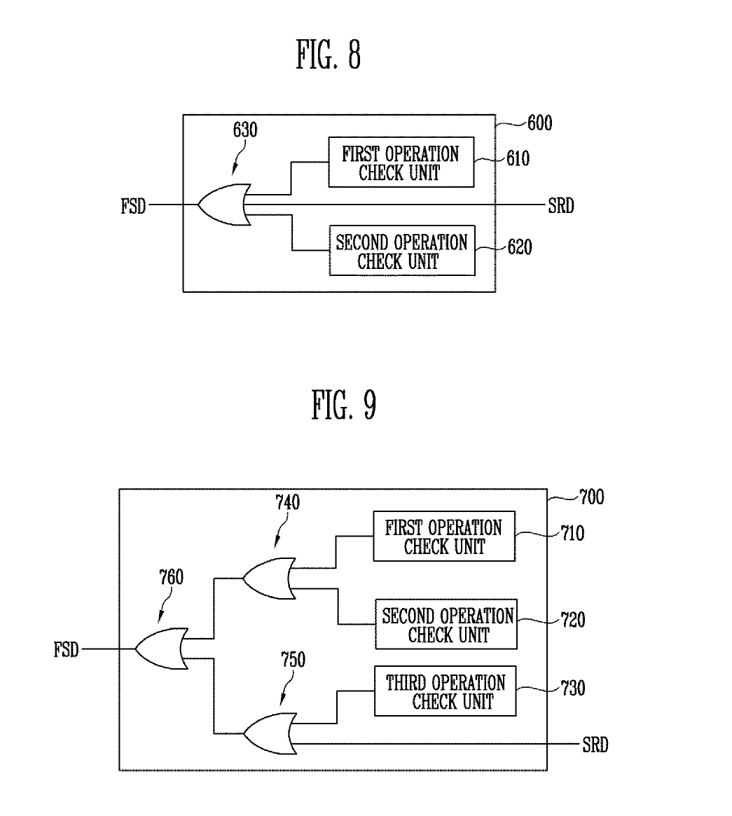

FIG. 8 is a block diagram illustrating another embodiment of the status check unit shown in FIG. 2.

Referring to FIG. 8, the status check unit 600 includes a first operation check unit 610, a second operation check unit 620, an OR circuit 630. As compared with the status check unit 300 of FIG. 4, the status check unit 600 of FIG. 8 includes two operation check units 610 and 620. The first and second operation check units 610 and 620 may be selected from the operation check units 310_1, 310_2, and 310_3 described with reference to FIGS. 5A to 5C. The OR circuit 630 performs a logical sum operation on first status check data output from the first operation check unit 610, second status check data output from the second operation check unit 620, and status read data SRD. Because the status check unit 600 shown in FIG. 8 includes the two operation check units 610 and 620, the operation status of the semiconductor memory device can be more accurately checked. Thus, the operational reliability of the semiconductor memory device is improved.

FIG. 9 is a block diagram illustrating still another embodiment of the status check unit shown in FIG. 2.

Referring to FIG. 9, the status check unit 700 includes a first operation check unit 710, a second operation check unit 720, a third operation check unit 730, and OR circuits. In FIG. 9, the OR circuits may be configured as OR gates 740, 750, and 760 shown in the drawing. As compared with the status check unit 600 of FIG. 8, the status check unit 700 of FIG. 9 includes three operation check units 710, 720, and 730. The first to third operation check units 710, 720, and 730 may correspond to the operation check units 310_1, 310_2, and 310_3 described with reference to FIGS. 5A to 5C, respectively. The OR gates 740, 750, and 760 perform a logical multiplication operation on the first status check data of the first operation check unit 710, second status check data of the second operation check unit 720, third status check data of the third operation check unit 730, and status read data SRD. Because the status check unit 700 shown in FIG. 9 includes the three operation check units 710, 720, and 730, the operation status of the semiconductor memory device can be more accurately checked. Thus, the operational reliability of the semiconductor memory device is improved.

The status check units shown in FIGS. 8 and 9 are configured to include OR circuits. However, as described with reference to FIG. 4, the status check units shown in FIGS. 8 and 9 may be configured to include AND circuits.

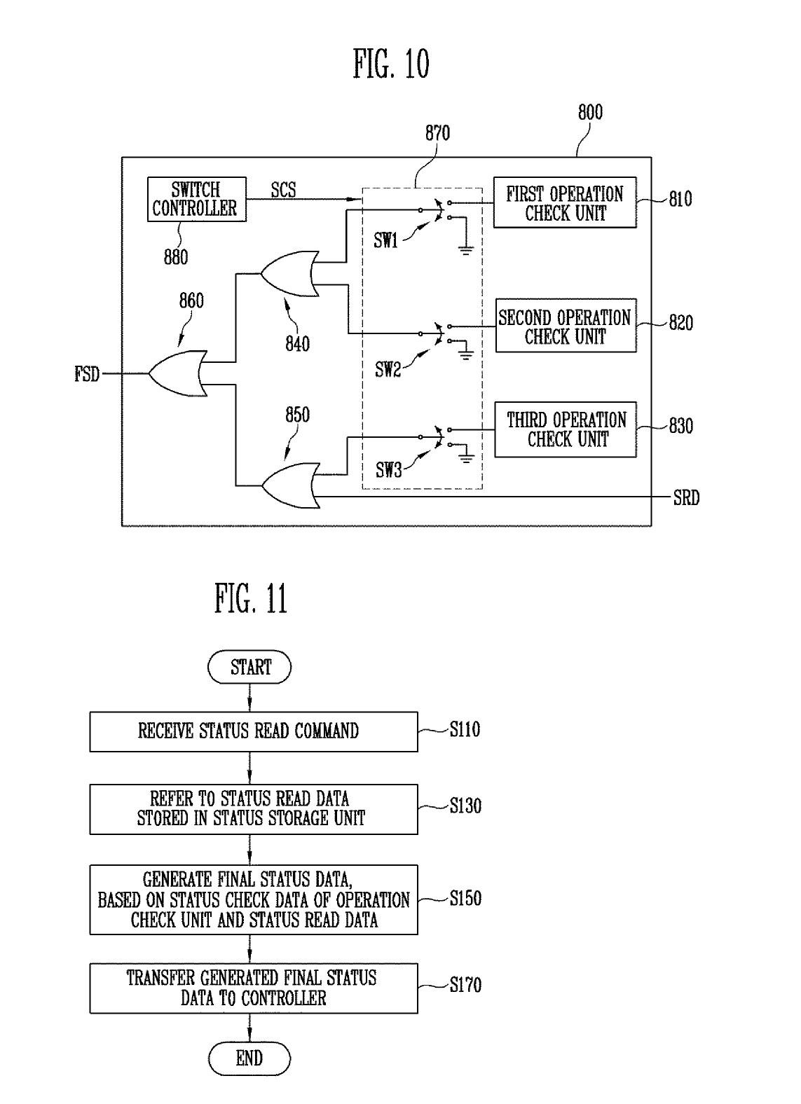

FIG. 10 is a block diagram illustrating still another embodiment of the status check unit shown in FIG. 2.

Referring to FIG. 10, the status check unit 800 is similar to the status check unit 700 of FIG. 9 in that the status check unit 800 includes a first operation check unit 810, a second operation check unit 820, a third operation check unit 830, and OR circuits 840, 850, and 860. However, the status check unit 800 of FIG. 10 is different from the status check unit 700 of FIG. 9 in that the status check unit 800 further includes a switching unit 870 and a switch control unit 880.

The switching unit 870 is disposed between the first to third operation check units 810, 820, and 830 and the OR circuits 840 and 850. The switching unit 870 includes first to third switches SW1 to SW3. The switch control unit 880 may control the switching unit 870. The first switch SW1 includes a first terminal coupled to an output terminal of the first operation check unit 810, a second terminal coupled to a ground, and a third terminal coupled to a first input terminal of the OR circuit 840. The first switch SW1 allows any one of the first terminal and the second terminal to be coupled to the third terminal, based on a switch control signal SCS received from the switch control unit 880. When the first terminal and the third terminal are coupled to each other, the OR circuit 840 receives status check data from the first operation check unit 810. Therefore, in this case, final status data FSD is generated by reflecting the status check data from the first operation check unit 810. On the other hand, when the second terminal and the third terminal are coupled to each other, the OR circuit 840 receives data indicating the logical value of “0” from a ground voltage. In this case, the status check data of the first operation check unit 810 is not transferred to the OR circuit 840, and therefore the status check data of the first operation check unit 810 is not transferred to the final status data FSD.

The second switch SW2 and the third switch SW3 also operate similar manner to the first switch SW1. Therefore, according to the switch control signal SCS received from the switch control unit 880, the final status data FSD may be generated by reflecting all status check data of the first to third operation check units 810, 820, and 830, the final status data FSD may be generated by reflecting some of the status check data of the first to third operation check units 810, 820, and 830, or the status check data of the first to third operation check units 810, 820, and 830 might not reflect generation of the final status data FSD. Thus, the final status data FSD can be generated by selectively reflecting the status check data of the first to third operation check units 810, 820, and 830 through control of the switch control unit 880, if necessary.

The status check unit 800 shown in FIG. 10 is configured using OR circuits. However, as described with reference to FIG. 4, the status check unit 800 shown in FIG. 10 may be configured to include AND circuits instead of OR circuits. In this case, the OR circuits 840, 850, and 860 are replaced with AND circuits, and the first to third operation check units 810, 820, and 830 transfer logically inverted status check data to the switching unit 870. In addition, the status read data SRD may be logically inverted to be input. Further, the second terminal of each of the switches SW1, SW2, and SW3 is not coupled to the ground but may be coupled to the power voltage having a logical value of “1.” It will be understood that data output from an AND circuit that replaces the OR circuit 860 may be logically inverted to be output as the final state data FSD. According to the above-described configuration, it will be understood that the final status data FSD that is the same output result of the status check unit 800 shown in FIG. 10 may be generated even when AND circuits are used.

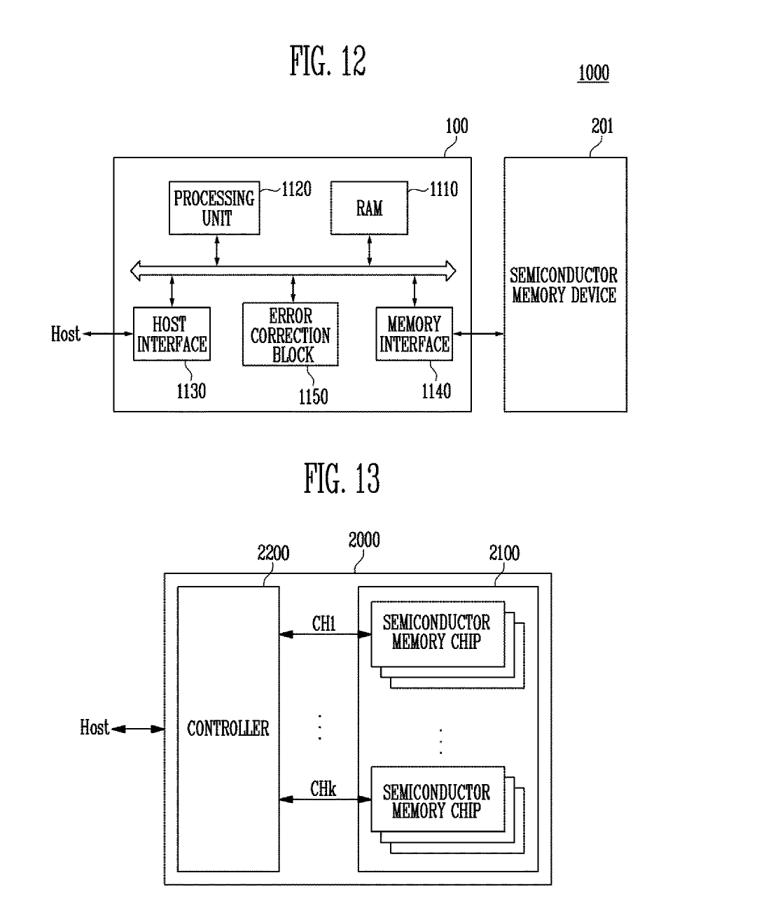

FIG. 11 is a flowchart illustrating a method for operating the semiconductor memory device according to an embodiment of the present disclosure.

Referring to FIG. 11, the method for operating the semiconductor memory device according to an embodiment of the present disclosure includes a step (S110) of receiving a status read command, a step (S130) of referring to status read data SRD stored in the status storage unit 230, a step (S150) of generating final status data FSD based on status check data SC of the operation check unit 310 and the status read data SRD, and a step (S170) of transferring the generated final status data FSD to the controller 100.

In step S110, the semiconductor memory device 201 receives a status read command from the controller 100. The status read command may be a command corresponding to the status read request SRR described with reference to FIGS. 1 and 2. In a configuration in which the semiconductor memory device 201 is directly coupled to a host as will be described later with reference to FIG. 14, the status read command may be received from the host.

In the step S130, status read data SRD stored in the status storage unit 230 is referred to. The referred to status read data SRD is transferred to the status check unit 240. The status check unit may be any one of the status check units shown in FIGS. 4, 8, 9, and 10.

In the step S150, final status data FSD is generated based on status check data SC of the operation check unit 310 and the status read data SRD. The operation check unit may also be any one of the operation check units shown in FIGS. 5A, 5B, and 5C. In some embodiments, final status data FSD may be generated based on status check data of two or more operation check units among the operation check units shown in FIGS. 5A, 5B, and 5C.

In the step S170, the generated final status data FSD is transferred to the controller 100. As shown in FIG. 3, the final status data FSD may be transferred to the controller 100 through the input/output interface 227. In the configuration in which the semiconductor memory device 201 is directly coupled to the host as will be described later with reference to FIG. 14, the final status data may be directly transferred to the host.

FIG. 12 is a block diagram illustrating a memory system including the semiconductor memory device of FIG. 3.

Referring to FIG. 12, the memory system 1000 includes a controller 100 and a semiconductor memory device 201. The semiconductor memory device may be the semiconductor memory device described with reference to FIG. 3. Also, the semiconductor memory device 201 may be the semiconductor memory device of the memory system 20 described with reference to FIG. 2. Hereinafter, overlapping descriptions will be omitted.

The controller 100 is coupled to a host Host and the semiconductor memory device 201. The controller 100 is configured to access the semiconductor memory device 201 in response to a request from the host Host. For example, the controller 100 is configured to control read, write, erase, and background operations of the semiconductor memory device 201. The controller 100 is configured to provide an interface between the semiconductor memory device 201 and the host Host. The controller 100 is configured to drive firmware for controlling the semiconductor memory device 201.

The controller 100 includes a random access memory (RAM) 1110, a processing unit 1120, a host interface 1130, a memory interface 1140, and an error correction block 1150. The RAM 1110 is used as at least one of an operation memory of the processing unit 1120, a cache memory between the semiconductor memory device 201 and the host Host, and a buffer memory between the semiconductor memory device 201 and the host Host. The processing unit 1120 controls overall operations of the controller 100. Also, the controller 100 may temporarily store program data provided from the host Host in a write operation.

The host interface 1130 includes a protocol for exchanging data between the host Host and the controller 100. In an exemplary embodiment, the controller 100 is configured to communicate with the host Host through at least one of various interface protocols such as a universal serial bus (USB) protocol, a multimedia card (MMC) protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, and a private protocol.

The memory interface 1140 interfaces with the semiconductor memory device 201. For example, the memory interface 1140 may include a NAND interface or a NOR interface.

The error correction block 1150 is configured to detect and correct an error of data received from the semiconductor memory device 201 by using an error correction code (ECC). The processing unit 1120 may control the semiconductor memory device 201 to adjust a read voltage, based on an error detection result of the error correction block 1150, and to perform re-reading. In an exemplary embodiment, the error correction block 1150 may be provided as a component of the controller 100.

The controller 100 and the semiconductor memory device 201 may be integrated into one semiconductor device. In an exemplary embodiment, the controller 100 and the semiconductor memory device 201 may be integrated into one semiconductor device, to constitute a memory card. For example, the controller 100 and the semiconductor memory device 201 may be integrated into one semiconductor device, to constitute a memory card such as a PC card (personal computer memory card international association (PCMCIA)), a compact flash (CF) card, a smart media card (SM or SMC), a memory stick, a multimedia card (MMC, RS-MMC or MMCmicro), an SD card (SD, miniSD, microSD or SDHC), or a universal flash storage (UFS).

The controller 100 and the semiconductor memory device 201 may be integrated into one semiconductor device to constitute a semiconductor drive (solid state drive (SSD)). The semiconductor drive SSD includes a storage device configured to store data in a semiconductor memory. If the memory system 1000 is used as the semiconductor drive SSD, the operating speed of the host Host coupled to the memory system 1000 can be remarkably improved.

As another example, the memory system 1000 may be provided as one of various components of an electronic device such as a computer, a ultra mobile PC (UMPC), a workstation, a net-book, a personal digital assistant (PDA), a portable computer, a web tablet, a wireless phone, a mobile phone, a smart phone, an e-book, a portable multimedia player (PMP), a portable game console, a navigation system, a black box, a digital camera, a 3-dimensional television, a digital audio recorder, a digital audio player, a digital picture recorder, a digital picture player, a digital video recorder, a digital video player, a device capable of transmitting/receiving information in a wireless environment, one of various electronic devices that constitute a home network, one of various electronic devices that constitute a computer network, one of various electronic devices that constitute a telematics network, an RFID device, or one of various components that constitute a computing system.

In an exemplary embodiment, the semiconductor memory device 201 or the memory system 1000 may be packaged in various forms. For example, the semiconductor memory device 201 or the memory system 1000 may be packaged in a manner such as package on package (PoP), ball grid arrays (BGAs), chip scale packages (CSPs), plastic leaded chip carrier (PLCC), plastic dual in-line package (PDIP), die in Waffle pack, die in wafer form, chip on board (COB), ceramic dual in-line package (CERDIP), plastic metric quad flat pack (MQFP), thin quad flat pack (TQFP), small outline integrated circuit (SOIC), shrink small out line package (SSOP), thin small outline package (TSOP), thin quad flat pack (TQFP), system in package (SIP), multi chip package (MCP), wafer-level fabricated package (WFP), or wafer-level processed stack package (WSP).

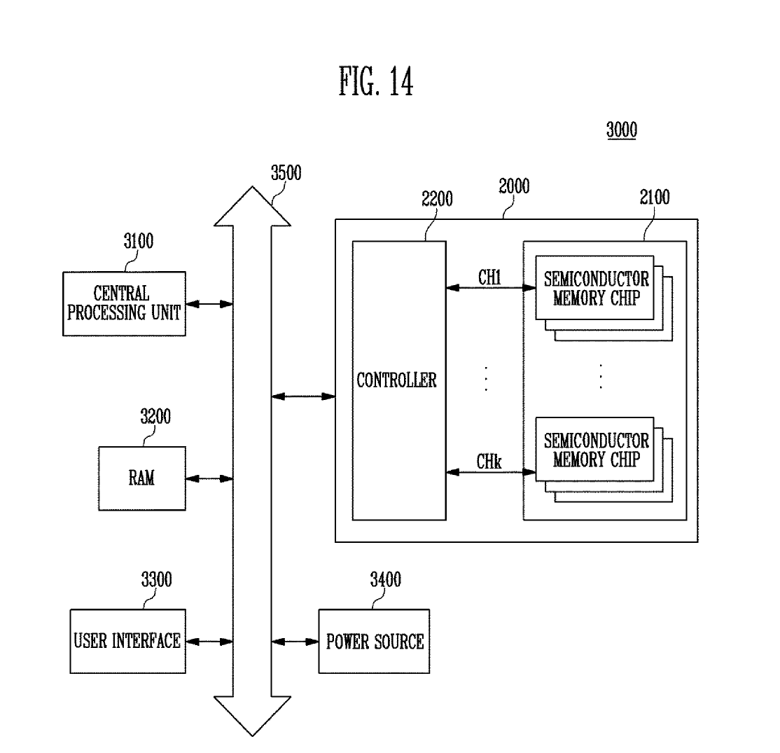

FIG. 13 is a block diagram illustrating an application example of the memory system of FIG. 12.

Referring to FIG. 13, the memory system 2000 includes a semiconductor memory device 2100 and a controller 2200. The semiconductor memory device 2100 includes a plurality of semiconductor memory chips. The plurality of semiconductor memory chips are divided into a plurality of groups.

In FIG. 13, it is illustrated that the plurality of groups communicate with the controller 2200 through first to kth channels CH1 to CHk. Each semiconductor memory chip may be configured and operated identically to one of the semiconductor memory devices 201 described with reference to FIGS. 2 and 3.

Each group is configured to communicate with the controller 2200 through one common channel. The controller 2200 is configured similar to the controller 100 described with reference to FIG. 12. The controller 2200 is configured to control the plurality of memory chips of the semiconductor memory device 2100 through the plurality of channels CH1 to CHk.

FIG. 14 is a block diagram illustrating a computing system including the memory system described with reference to FIG. 13.

Referring to FIG. 14, the computing system 300 includes a central processing unit 3100, a RAM 3200, a user interface 3300, a power source 3400, a system bus 3500, and a memory system 2000.

The memory system 2000 is electrically coupled to the central processing unit 3100, the RAM 3200, the user interface 3300, and the power source 3400 through the system bus 3500. Data supplied through user interface 3300 or data processed by the central processing unit 3100 are stored in the memory system 2000.

In FIG. 14, it is illustrated that the semiconductor memory device 2100 is coupled to the system bus 3500 through the controller 2200. However, the semiconductor memory device 2100 may be directly coupled to the system bus 3500. In this case, the function of the controller 2200 may be performed by the central processing unit 3100 and the RAM 3200.

In FIG. 14, it is illustrated that the memory system 2000 described with reference to FIG. 13 is provided. However, the memory system 2000 may be replaced by the memory system 1000 described with reference to FIG. 12. In an exemplary embodiment, the computing system 3000 may be configured to include both of the memory systems 1000 and 2000 described with reference to FIGS. 12 and 13.

According to the present disclosure, it is possible to provide a semiconductor memory device capable of improving the reliability of an operation.

Further, according to the present disclosure, it is possible to provide a method for operating a semiconductor memory device capable of improving the reliability of an operation.

Example embodiments have been disclosed herein, and although specific terms are employed, they are used and are to be interpreted in a generic and descriptive sense only and not for the purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present disclosure as set forth in the following claims.

What is claimed is:

1. A semiconductor memory device comprising:
a status storage unit configured to store first status data indicating an operation status of a memory cell array; and
a status check unit configured to generate second status data, based on the first status data and an operation of the memory cell array.

2. The semiconductor memory device of claim 1, wherein the status storage unit is configured with a status register.

3. The semiconductor memory device of claim 1, wherein the status check unit includes:
at least one operation check unit configured to generate status check data by checking the operation of the memory cell array; and
a logical sum circuit (OR circuit) configured to receive the status check data and the first status data and output the second status data.

4. The semiconductor memory device of claim 3, wherein the operation check unit outputs a logical value of “0” as the status check data when the operation of the memory cell array is completed, and outputs a logical value of “1” as the status check data when the operation of the memory cell array has not completed.

5. The semiconductor memory device of claim 3, wherein the operation check unit includes:
a program pulse counter configured to count a number of times of that a program pulse is applied to the memory cell array in the program operation;
a reference count storage unit configured to store a reference count value that becomes a generation reference of the status check data; and
a pulse count comparing unit configured to generate the status check data by comparing the number of times that the program pulse is applied, which is stored in the program pulse counter, and the reference count value.

6. The semiconductor memory device of claim 5, wherein the pulse count comparing unit generates the logical value of “1” as the status check data when the number of times that the program pulse is applied is less than the reference count value, and generates the logical value of “0” as the status check data when the number of times that the program pulse is applied is greater than or equal to the reference count value.

7. The semiconductor memory device of claim 3, wherein the operation check unit includes:
a current sensing circuit configured to generate a check signal indicating whether at least some memory cells among selected memory cells have reached a target threshold voltage in the program operation; and
a sensing result storage unit configured to store the check signal as the status check data.

8. The semiconductor memory device of claim 7, wherein the sensing result storage unit stores the logical value of “1” as the status check data when the number of memory cells that reach the target threshold voltage among the selected memory cells is less than a predetermined first reference value, and stores the logical value of “0” as the status check data when the number of memory cells that reach the target threshold voltage among the selected memory cells is greater than or equal to the first reference value.

9. The semiconductor memory device of claim 3, wherein the operation check unit includes:
a fail bit counter configured to count a number of memory cells that do not reach a target threshold voltage among selected memory cells in the program operation;
a reference bit number storage unit configured to store a reference bit number that becomes a generation reference of the status check data; and
a fail bit comparing unit configured to generate the status check data by comparing the reference bit number stored in the reference bit number storage unit and the counted result of the fail bit counter.

10. The semiconductor memory device of claim 9, wherein the fail bit comparing unit generates the logical value of “1” as the status check data when the counted result is greater than the reference bit number, and generates the logical value of “0” as the status check data when the counted result is less than or equal to the reference bit number.

11. The semiconductor memory device of claim 3, wherein the status check unit further includes:
a switching unit disposed between at least one operation check unit and the OR circuit; and
a switch control unit configured to control the switching unit.

12. The semiconductor memory device of claim 11, wherein the switching unit includes at least one switch including a first terminal coupled to an output terminal of the at least one operation check unit, a second terminal coupled to a ground, and a third terminal coupled to an input terminal of the OR circuit,
wherein the switch is configured to allow any one of the first terminal and the second terminal to be selectively coupled to the third terminal, based on a switch control signal received from the switch control unit.

13. The semiconductor memory device of claim 1, wherein the status check unit includes:
at least one operation check unit configured to generate status check data by checking the operation of the memory cell array; and
a logical multiplication circuit (AND circuit) configured to receive the status check data and the first status data to output the second status data.

14. The semiconductor memory device of claim 13, wherein the status check unit further includes:
a switching unit disposed between the at least one operation check unit and the AND circuit; and
a switch control unit configured to control the switching unit.

15. The semiconductor memory device of claim 14, wherein the switching unit includes at least one switch including a first terminal coupled to an output terminal of the at least one operation check unit, a second terminal coupled to a power voltage, and a third terminal coupled to an input terminal of the AND circuit,
wherein the switch is configured to allow any one of the first terminal and the second terminal to be selectively coupled to the third terminal, based on a switch control signal received from the switch control unit.

16. The semiconductor memory device of claim 1, wherein the status check unit includes:
first and second operation check units configured to respectively generate first and second status check data by checking the operation of the memory cell array; and
an OR circuit configured to receive the first and second status check data and the first status data to output the second status data.

17. The semiconductor memory device of claim 16, wherein the first operation check unit includes:
a program pulse counter configured to count a number of times that a program pulse is applied to the memory cell array in the program operation;
a reference count storage unit configured to store a reference count value that becomes a generation reference of the status check data; and
a pulse count comparing unit configured to generate the first status check data by comparing the number of times that the program pulse is applied, which is stored in the program pulse counter, and the reference count value.

18. The semiconductor memory device of claim 17, wherein the pulse count comparing unit generates the logical value of “1” as the first status check data when the number of times that the program pulse is applied is less than the reference count value, and generates the logical value of “0” as the first status check data when the number of times that the program pulse is applied is greater than or equal to the reference count value.

19. The semiconductor memory device of claim 17, wherein the second operation check unit includes:
a current sensing circuit configured to generate a check signal indicating whether at least some memory cells among selected memory cells have reached a target threshold voltage in the program operation; and
a sensing result storage unit configured to store the check signal as the second status check data.

20. The semiconductor memory device of claim 19, wherein the sensing result storage unit stores the logical value of “1” as the second status check data when the number of memory cells that reach the target threshold voltage among the selected memory cells is less than a predetermined first reference value, and stores the logical value of “0” as the second status check data when the number of memory cells that reach the target threshold voltage among the selected memory cells is greater than or equal to the first reference value.

21. The semiconductor memory device of claim 17, wherein the second operation check unit includes:
a fail bit counter configured to count a number of memory cells that do not reach a target threshold voltage among selected memory cells in the program operation;
a reference bit number storage unit configured to store a reference bit number that becomes a generation reference of the status check data; and
a fail bit comparing unit configured to generate the second status check data by comparing the reference bit number stored in the reference bit number storage unit and the counted result of the fail bit counter.

22. The semiconductor memory device of claim 21, wherein the fail bit comparing unit generates the logical value of “1” as the second status check data when the counted result is greater than the reference bit number, and generates the logical value of “0” as the second status check data when the counted result is less than or equal to the reference bit number.

23. The semiconductor memory device of claim 1, wherein the status check unit includes:
first, second, and third operation check units configured to respectively generate first, second, and third status check data by checking the operation of the memory cell array; and
an OR circuit configured to receive the first, second, and third status check data and the first status data to output the second status data.

24. The semiconductor memory device of claim 23, wherein the first operation check unit includes:
a program pulse counter configured to count a number of times that a program pulse is applied to the memory cell array in the program operation;
a reference count storage unit configured to store a reference count value that becomes a generation reference of the status check data; and
a pulse count comparing unit configured to generate the first status check data by comparing the number of times that the program pulse is applied, which is stored in the program pulse counter, and the reference count value,
wherein the second operation check unit includes:
a current sensing circuit configured to generate a check signal indicating whether at least some memory cells among selected memory cells have reached a target threshold voltage in the program operation; and
a sensing result storage unit configured to store the check signal as the second status check data, and
wherein the third operation check unit includes:
a fail bit counter configured to count a number of memory cells that do not reach a target threshold voltage among selected memory cells in the program operation;
a reference bit number storage unit configured to store a reference bit number that becomes a generation reference of the status check data; and
a fail bit comparing unit configured to generate the third status check data by comparing the reference bit number stored in the reference bit number storage unit and the counted result of the fail bit counter.
